(19) United States
(12) Patent Application Publication
(10) Pub. No.: US 2019/0067427 A1
(43) Pub. Date: Feb. 28, 2019

(54) INTER-POLY OXIDE IN FIELD EFFECT TRANSISTORS

(71) Applicant: SEMICONDUCTOR COMPONENTS INDUSTRIES, LLC, Phoenix, AZ (US)

(72) Inventors: Peter A. BURKE, Portland, OR (US); Dean E. PROBST, West Jordan, UT (US); Sallie J. HOSE, Gresham, OR (US)

(73) Assignee: SEMICONDUCTOR COMPONENTS INDUSTRIES, LLC, Phoenix, AZ (US)

(21) Appl. No.: 15/836,328

(22) Filed: Dec. 8, 2017

Related U.S. Application Data
(60) Provisional application No. 62/549,873, filed on Aug. 24, 2017.

(51) Int. Cl. H01L 29/40; H01L 21/28; H01L 29/423

(52) U.S. Cl. CPC H01L 29/401; H01L 21/28273; H01L 29/407; H01L 29/42364; H01L 21/28114; H01L 21/28185; H01L 29/4236

(57) ABSTRACT

A method of forming a shielded gate field effect transistor includes forming a trench within a substrate and depositing a shield oxide material within the trench, which is then recessed. The method further includes depositing a shield electrode material on the shield oxide material and recessing the shield oxide material within the trench to widen an upper portion of the trench. The method further includes recessing the shield electrode material thus forming a recession and depositing an inter-poly oxide material on the shield electrode material into the recession, thus filling the recession. The method further includes forming a gate electrode above the inter-poly oxide material.

### CROSS-REFERENCE TO RELATED APPLICATION

This application claims the benefit of U.S. Provisional Application No. 62/549,873, titled “IGBT and MOSFET Device Improvements” and filed Aug. 24, 2017.

### BACKGROUND

Metal-oxide semiconductor field-effect transistors (“MOSFETs”) are a common type of power switching device. A MOSFET device includes a source region, a drain region, a channel region extending between the source and drain regions, and a gate structure provided adjacent to the channel region. The gate structure includes a conductive gate electrode layer disposed adjacent to, and separated from the channel region by, a dielectric layer. When a MOSFET device is in the on state, a voltage is applied to the gate structure to form a conduction channel region between the source and drain regions, which allows current to flow through the device. In the off state, any voltage applied to the gate structure is sufficiently low so that a conduction channel does not form, and thus current flow does not occur. In the off state, the device may support a high voltage between the source region and the drain region.

Shielded gate MOSFETs provide several advantages over conventional MOSFETs in certain applications because shielded gate MOSFETs exhibit reduced gate-to-drain capacitance, C_{gd}, reduced on-resistance, R_{ds(on)}, and increased breakdown voltage. For conventional MOSFETs, the placement of many trenches in a channel, while decreasing the on-resistance, increases the overall gate-to-drain capacitance. Shielded gate MOSFETs remedy this issue by shielding the gate from the electric field, thereby substantially reducing the gate-to-drain capacitance. The shielded gate MOSFET structure also provides higher minority carrier concentration for the device's breakdown voltage and, hence, lower on-resistance.

These improved performance characteristics of shielded gate MOSFETs make them preferable for certain applications. However, production of shielded gate MOSFETs require more processes than conventional MOSFETs, thus increasing costs and decreasing reliability.

### SUMMARY

Accordingly, systems and methods for using inter-poly oxide in field effect transistors are disclosed herein. Use of an inter-poly oxide reduces the number of processes in the production of shielded gate MOSFETs, which decreases costs and increases reliability even with respect to other shielded gate MOSFETs.

A method of forming a shielded gate field effect transistor includes forming a trench within a substrate and depositing a shield oxide material within the trench. The method further includes depositing a shield electrode material on the shield oxide material and recessing the shield oxide material within the trench to widen an upper portion of the trench. The method further includes recessing the shield electrode material thus forming a recession and depositing an inter-poly oxide material on the shield electrode material into the recession, thus filling the recession. The method further includes forming a gate electrode above the inter-poly oxide material.

A shielded gate field effect transistor includes a substrate, a shield electrode, a gate electrode, and a shield oxide between the shield electrode and the substrate. The transistor further includes an inter-poly oxide between the gate electrode and the shield electrode. The inter-poly oxide is at least 800 angstroms thick.

A method of forming a shielded gate field effect transistor includes recessing shield electrode material thus forming a recession. The method further includes depositing an inter-poly oxide material with a thickness of at least 800 angstroms on the shield electrode material into the recession, thus filling the recession. The method further includes forming a gate electrode above the inter-poly oxide material.

### BRIEF DESCRIPTION OF THE DRAWINGS

Systems and methods for using inter-poly oxide in field effect transistors are disclosed herein. In the drawings:

FIG. 1 is a cross-sectional schematic diagram illustrating a shielded gate MOSFET;

FIGS. 2A-2E are cross-sectional schematic diagrams illustrating a method for manufacturing a shielded gate MOSFET; and

FIG. 3 is a flow diagram illustrating a method for manufacturing a shielded gate MOSFET.

It should be understood, however, that the specific embodiments given in the drawings and detailed description thereto do not limit the disclosure. On the contrary, they provide the foundation for one of ordinary skill to discern the alternative forms, equivalents, and modifications that are encompassed together with one or more of the given embodiments in the scope of the appended claims.

### NOTATION AND NOMENCLATURE

Certain terms are used throughout the following description and claims to refer to particular system components and configurations. As one of ordinary skill will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ”. Also, the term “couple” or “couples” is intended to mean either an indirect or a direct electrical or physical connection. Thus, if a first device couples to a second device, that connection may be through a direct electrical connection, through an indirect electrical connection via other devices and connections, through a direct physical connection, or through an indirect physical connection via other devices and connections in various embodiments.

Directional terminology, such as “top,” “bottom,” “front,” “back,” “leading,” “trailing,” etc., is used with reference to the orientation of the figure(s) being described. It is to be understood that other embodiments may be utilized and structural or logical changes may be made without departing from the scope of the present disclosure.

For convenience, use of + or − after a designation of conductivity or charge carrier type (p or n) refers generally to a relative degree of concentration of designated type of charge carriers within a semiconductor material. In general, an n+ material has a higher negative charge carrier (e.g., electron) concentration than an n material, and an n material has a higher carrier concentration than an n− material. Similarly, a p+ material has a higher positive charge carrier (e.g., hole) concentration than a p material, and a p material has a higher concentration than a p− material. As used herein, a concentration of dopants less than about 1016/cm³ may be regarded as “lightly doped” and a concentration of dopants greater than about 1017/cm³ may be regarded as “heavily doped”.

### DETAILED DESCRIPTION

A relatively thick layer of inter-poly oxide used in shielded gate MOSFETs improves reliability and decreases the number of processes used during production. Specifically, a relatively thick inter-poly oxide reduces input capacitance and switching losses, and some masking and etching processes may be eliminated as described below with respect to the figures.

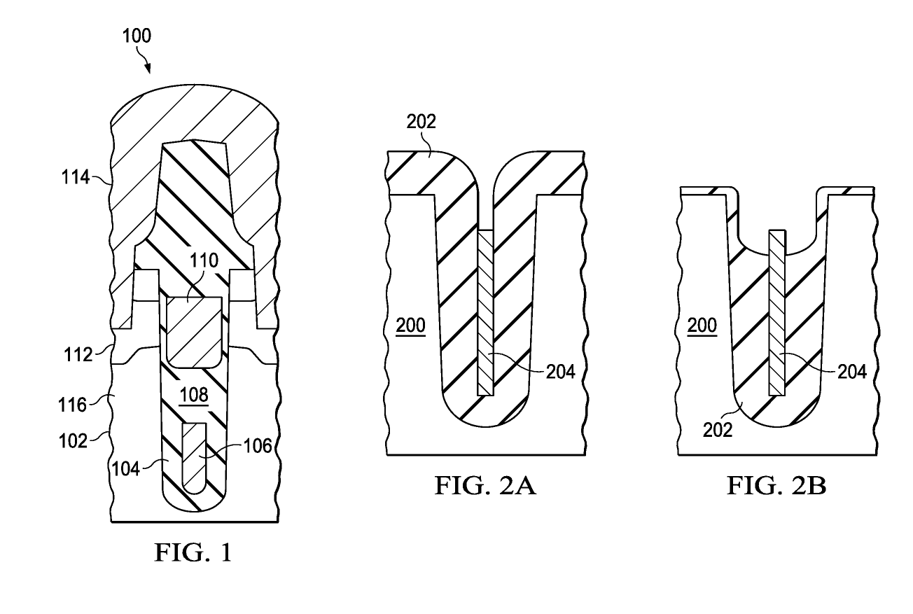

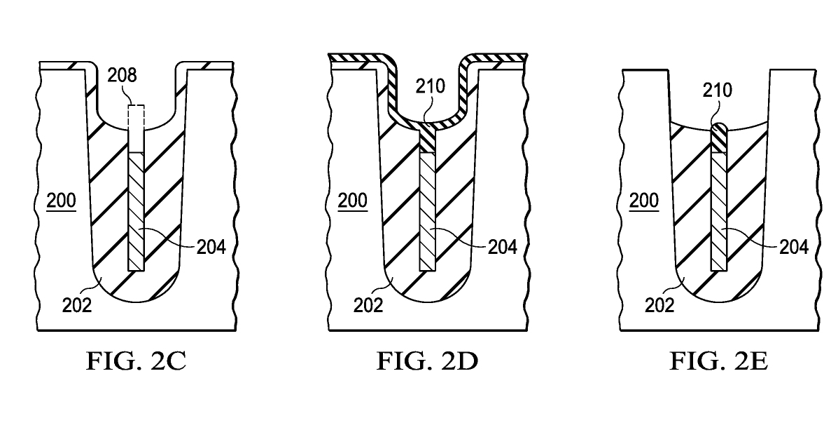

The semiconductor materials forming the various layers of FIGS. 1 and 2A-2E may include a variety of different materials, e.g., silicon, doped silicon, silicon/germanium, germanium, a group III-V material, etc. The layers may be formed to any desired thickness using an appropriate process, e.g., an epitaxial growth process, a deposition process, an ion implantation process, a chemical vapor deposition (CVD) process, an atomic layer deposition (ALD) process, an epitaxial deposition process (EPI), plasma versions of such processes, a wet or dry etching process, an anisotropic etching process, an isotropic etching process, an etching through hard mask process, a timed etch, a stop-on-contact etch, etc. The various layers may be leveled using a chemical mechanical polishing (“CMP”) process, and the shape of the etched portions, and hence the shape of the layers, may be manipulated using masking processes. The masking material may include a photoresist which has been patterned using photolithography. Specifically, a masking layer protects the structures underneath the masking layer from the etchant. The etchant is used to remove portions of the structures not protected by the masking layer. The formulas for common etchants are HNO₃, HF, KOH, EDP, TMAH, NH₄F, and H₃PO₄. Other etchants may be used as well.

FIG. 1 illustrates a cross-section of a portion of a semiconductor device 100, e.g. a shielded gate MOSFET, including a substrate 102, a shield oxide 104, a shield electrode 106, an inter-poly oxide 108, a gate electrode 110, body regions 112, and a source region 114. The substrate 102 may be an n-doped or p-doped silicon layer, and may be formed on top of another layer. The shield oxide 104 is between the substrate 102 and the shield electrode 106, and the inter-poly oxide 108 is between the gate electrode 108 and the shield electrode 106. The shield oxide 104 and inter-poly oxide 108 may include oxides such as silicon dioxide, silicon dioxide doped with boron (BSG), or the like. The gate electrode 110 and source region 114 provide two terminals of the MOSFET 100, and the body regions 112 separate the source region 114 and drain region 116 by having the opposite type material (n or p) to the source and drain regions. The source region 114 may be a metal such as titanium disilicide, titanium nitride, tungsten, aluminum, a combination of the preceding, and/or the like.

As mentioned above, the inter-poly oxide 108 is relatively thick. Specifically, the inter-poly oxide 108 is at least 800 angstroms thick in some embodiments, and is between 800 and 3,000 angstroms thick in some embodiments. For example, the inter-poly oxide is 1,500 angstroms thick in at least one embodiment. The inter-poly oxide 108 may be spin-on glass, and may be doped, e.g. with boron, to increase etch rate and etch selectivity. The doping may occur before, during, or after deposition. The thickness of the inter-poly oxide 108 may be independent of the gate electrode thickness 110, and the inter-poly oxide 108 may be at least three times as thick as the gate electrode 110.

FIGS. 2A-2E are cross-sectional schematic diagrams illustrating a method for manufacturing a shielded gate MOSFET. In FIG. 2A, a trench has been formed in a substrate 200 using masking and etch techniques described above. The substrate 200 may include silicon in a relatively lightly doped n-type epitaxial layer extending over a highly conductive n-type material (not shown). A shield oxide layer 202 (e.g., comprising an oxide) has been deposited to line the trench sidewalls and bottom as well as the surface of the substrate 200. The shield oxide layer 202 may be formed using high temperature (e.g., 1,150° C.) dry oxidation to a thickness of about 1,250 angstroms. The shield oxide layer 202 may then be recessed if desired. A layer of polysilicon has been deposited to fill the trench above the shield oxide layer 202. The deposited polysilicon has been recessed into the trench to form a shield electrode 204.

In FIG. 2B, the exposed portions of the shield oxide layer 202 have been recessed. For example, a wet buffered oxide etch may be used to recess the shield oxide layer 202 without affecting the shield electrode 204. In FIG. 2C, the shield electrode 204 has been recessed, thus creating a recession. Specifically, the top surface of the shield electrode 204 is lower than the top surface of the shield electrode layer 202 within the trench. In FIG. 2D, a conformal layer of inter-poly oxide 210 has been deposited on the shield electrode 204 and shield oxide layer 202 causing the recession to be filled. In at least one embodiment, the thickness of the inter-poly oxide 210 is at least half of the width of the recession. An anneal or thermal treatment may be performed to eliminate any seam formed during the deposition of the conformal inter-poly oxide 210.

In FIG. 2E, the inter-poly oxide 210 and shield oxide layer 202 have been etched to a desired depth and thickness. Specifically, the inter-poly oxide 210 should be relatively thick as described above. The shield oxide over the surface of the substrate 200 and along the upper trench sidewalls has been completely removed, and an inter-poly oxide 210 layer having a concave top surface remains over the shield electrode 204. The inter-poly oxide 210 does not include a thermal dielectric layer, and any deposition or etching processes related to a thermal dielectric layer are not performed. A dry anisotropic plasma etch or a wet etch may be performed to achieve the desired thickness of the inter-poly oxide 210 and to ensure that the shield oxide layer 202 along the trench sidewalls and over the substrate 200 is completely removed.

At this point, known gate formation techniques may be applied resulting in the device 100 shown in FIG. 1. For example, gate electrode material 110 may be either grown, deposited, or a combination of grown/deposited over the inter-poly oxide 210. Because inter-poly oxide 210 formation is independent of gate electrode formation, the gate electrode 110 can be independently optimized to have desired characteristics. Next, the gate electrode material 110 extending over the substrate 200 may be etched or polished flat to the top of the substrate to a thickness suitable for body implantation 112 and source formation 114.

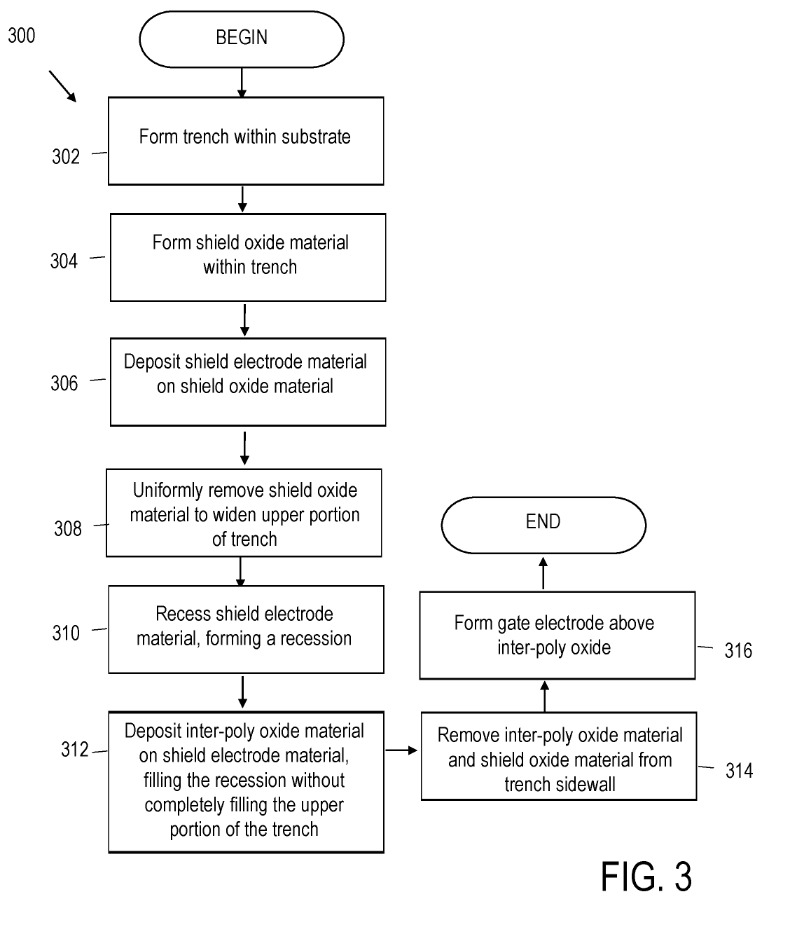

FIG. 3 is a flow diagram illustrating a method 300 for manufacturing a shielded gate MOSFET. At 302, a trench is formed within a substrate using the etching and masking processes described above. The substrate may include silicon in a relatively lightly doped n-type epitaxial layer extending over a highly conductive n-type material. At 304, a shield oxide material is deposited within the trench. For example, the shield oxide material may be deposited to line the trench sidewalls and bottom as well as the surface of the substrate.

At 306, a shield electrode material is deposited on the shield oxide material. For example, a layer of polysilicon may be deposited to fill the trench above the shield oxide layer. The method may further include recessing the shield electrode material before recessing the shield oxide material, thus forming a shield electrode. At 308, the shield oxide material within the trench is recessed to widen an upper portion of the trench. For example, a wet buffered oxide etch may be used to recess the shield oxide layer without affecting the shield electrode. At 310, the shield electrode material is recessed thus forming a recession. For example, the top surface of the shield electrode may be recessed to be lower than the top surface of the shield electrode layer within the trench.

At 312, an inter-poly oxide material is deposited on the shield electrode material into the recession, thus filling the recession without completely filling the upper portion of the trench. Depositing the inter-poly oxide material may include depositing the inter-poly oxide material with a thickness of at least 800 angstroms or with a thickness between 800 angstroms and 3,000 angstroms. An even thicker layer of inter-poly oxide material may be deposited, and then recessed or etched to be between 800 angstroms and 3,000 angstroms thick. The inter-poly oxide material may be spin-on glass.

At 314, the inter-poly oxide is etched from the trench sidewall. Additionally, the inter-poly oxide material may be etched from the shield oxide material formed on sidewalls of the trench and a surface of the substrate. The method 300 may further include etching the shield oxide material formed on sidewalls of the trench and a surface of the substrate. Finally, etching the inter-poly oxide material and shield oxide material may be performed on sidewalls of the trench and a surface of the substrate in one etch. The method may further include doping the inter-poly oxide material to increase etch rate and etch selectivity. Doping the inter-poly oxide material may include doping the inter-poly oxide material with boron. At 316, a gate electrode is formed above the inter-poly oxide.

Although a number of specific embodiments are shown and described above, embodiments of the disclosure are not limited thereto. For example, it is understood that the doping polarities of the structures shown and described could be reversed and/or the doping concentrations of the various elements could be altered. The process sequence depicted by FIGS. 2A-2E may be modified for forming an n-channel FET or a p-channel FET. Also, while the various embodiments described above are implemented in conventional silicon, these embodiments and their obvious variants can also be implemented in silicon carbide, gallium arsenide, gallium nitride, diamond or other semiconductor materials. Furthermore, the cross-section views of the different embodiments may not be to scale, and as such are not intended to limit the possible variations in the layout design of the corresponding structures. Moreover, the features of one or more embodiments of the disclosure may be combined with one or more features of other embodiments of the disclosure without departing from the scope of the disclosure. Hence, the scope of this disclosure is defined by the claims.

In some aspects systems and method for obstacle monitoring are provided according to one or more of the following examples:

Example 1: A method of forming a shielded gate field effect transistor includes forming a trench within a substrate and depositing a shield oxide material within the trench, which is then recessed. The method further includes depositing a shield electrode material on the shield oxide material and recessing the shield oxide material within the trench to widen an upper portion of the trench. The method further includes recessing the shield electrode material thus forming a recession and depositing an inter-poly oxide material on the shield electrode material into the recession, thus filling the recession. The method further includes forming a gate electrode above the inter-poly oxide material.

Example 2: A shielded gate field effect transistor includes a substrate, a shield electrode, a gate electrode, and a shield oxide between the shield electrode and the substrate. The transistor further includes an inter-poly oxide between the gate electrode and the shield electrode. The inter-poly oxide is at least 800 angstroms thick.

Example 3: A method of forming a shielded gate field effect transistor includes recessing shield electrode material thus forming a recession. The method further includes depositing an inter-poly oxide material with a thickness of at least 800 angstroms on the shield electrode material into the recession, thus filling the recession. The method further includes forming a gate electrode above the inter-poly oxide material.

The following features may be incorporated into the various embodiments described above, such features incorporated either individually in or conjunction with one or more of the other features. Depositing the inter-poly oxide material may include depositing the inter-poly oxide material with a thickness of at least 800 angstroms. Depositing the inter-poly oxide material may include depositing the inter-poly oxide material with a thickness between 800 angstroms and 3,000 angstroms. The method may further include recessing the shield electrode material before recessing the shield oxide material. The method may further include etching the inter-poly oxide material from the shield oxide material formed on sidewalls of the trench and a surface of the substrate. The method may further include etching the shield oxide material formed on sidewalls of the trench and a surface of the substrate. The method may further include etching the inter-poly oxide material and shield oxide material formed on sidewalls of the trench and a surface of the substrate in one etch. The inter-poly oxide material may include spin-on glass. The method may further include doping the inter-poly oxide material to increase etch rate and etch selectivity. Doping the inter-poly oxide material may include doping the inter-poly oxide material with boron. The inter-poly oxide may be between 800 and 3,000 angstroms thick. The inter-poly oxide may be doped to increase etch rate and etch selectivity. The inter-poly oxide may be doped with boron. The inter-poly oxide thickness may be independent of the gate electrode thickness. The inter-poly oxide thickness may be at least three times the gate electrode thickness.

Numerous other modifications, equivalents, and alternatives, will become apparent to those skilled in the art once the above disclosure is fully appreciated. It is intended that the following claims be interpreted to embrace all such modifications, equivalents, and alternatives where applicable.

1. A method of manufacturing a shielded gate field effect transistor comprising:
forming a trench within a substrate;
forming a shield oxide material within the trench;
depositing a shield electrode material on the shield oxide material;
recessing the shield electrode material within the trench;
recessing the shield oxide material within the trench to widen an upper portion of the trench;
recessing the shield electrode material thus forming a recession; and
depositing an inter-poly oxide material on the shield electrode material into the recession, thus filling the recession.

2. The method of claim 1, wherein depositing the inter-poly oxide material comprises depositing the inter-poly oxide material with a thickness of at least half of the width of the recession.

3. The method of claim 1, wherein depositing the inter-poly oxide material comprises depositing the inter-poly oxide material with a thickness between 800 angstroms and 3,000 angstroms.

4. The method of claim 1, further comprising recessing the shield electrode material before recessing the shield oxide material.

5. The method of claim 1, further comprising etching the inter-poly oxide material from the shield oxide material formed on sidewalls of the trench and a surface of the substrate.

6. The method of claim 5, further comprising etching the shield oxide material formed on sidewalls of the trench and a surface of the substrate.

7. The method of claim 1, further comprising etching the inter-poly oxide material and shield oxide material formed on sidewalls of the trench and a surface of the substrate in one etch.

8. The method of claim 1, wherein the inter-poly oxide material comprises spin-on glass.

9. The method of claim 1, further comprising doping the inter-poly oxide material to increase etch rate and etch selectivity.

10. The method of claim 9, wherein doping the inter-poly oxide material comprises doping the inter-poly oxide material with boron.

11. A shielded gate field effect transistor comprising:
a substrate;
a shield electrode;
a gate electrode;
a shield oxide between the shield electrode and the substrate; and
an inter-poly oxide between the gate electrode and the shield electrode, wherein the inter-poly oxide is at least 800 angstroms thick.

12. The transistor of claim 11, wherein the inter-poly oxide is between 800 and 3,000 angstroms thick.

13. The transistor of claim 11, wherein the inter-poly oxide comprises spin-on glass.

14. The transistor of claim 11, wherein the inter-poly oxide is doped to increase etch rate and etch selectivity.

15. The transistor of claim 14, wherein the inter-poly oxide is doped with boron.

16. The transistor of claim 11, wherein the inter-poly oxide thickness is independent of the gate electrode thickness.

17. The transistor of claim 11, wherein the inter-poly oxide thickness is at least three times the gate electrode thickness.

18. A method of manufacturing a shielded gate field effect transistor comprising:
recessing shield electrode material thus forming a recession;
depositing an inter-poly oxide material with a thickness of at least 800 angstroms on the shield electrode material into the recession, thus filling the recession; and
forming a gate electrode above the inter-poly oxide material.

19. The method of claim 18, wherein depositing the inter-poly oxide material comprises depositing the inter-poly oxide material with a thickness between 800 angstroms and 3,000 angstroms.

20. The method of claim 18, wherein depositing the inter-poly oxide material comprises depositing the inter-poly oxide material with a thickness of at least half of the width of the recession.
